(19) United States
(12) Patent Application Publication
(10) Pub. No.: US 2026/0068235 A1
(43) Pub. Date: Mar. 5, 2026

(54) SEMI-FLOATING JUNCTION ISOLATION

(71) Applicant: TEXAS INSTRUMENTS INCORPORATED, Dallas, TX (US)

(72) Inventors: Ali Saadat, Santa Clara, CA (US); Clint Naquin, Plano, TX (US); Henry Litzmann Edwards, Garland, TX (US); Timothy Bryan Merkin, Princeton, TX (US); Archana Venugopal, Mountain View, CA (US)

(21) Appl. No.: 18/819,873

(22) Filed: Aug. 29, 2024

(51) Int. Cl. H01L 29/78; H01L 27/06; H01L 29/40; H01L 29/45

(52) U.S. Cl. CPC H10D 30/711; H10D 30/65; H10D 64/111; H10D 64/62; H10D 84/811

(57) ABSTRACT

The present disclosure generally relates to semi-floating junction isolation. In an example, a semiconductor device includes an epitaxial layer, a buried layer, a deep well, a drift well, a contact well, and a contact region. The buried layer, deep well, drift well, contact well, and contact region each have a conductivity type opposite from a conductivity type of the epitaxial layer. The buried layer is spaced apart from a top surface of the epitaxial layer. The deep well extends in the epitaxial layer and touches the buried layer. The deep well laterally encircles an active area over the buried layer. The drift well extends in the epitaxial layer to a depth and extends laterally from the deep well towards the active area. The contact well extends in the epitaxial layer to a greater depth and touching the drift well. The contact region extends in the contact well.

### BACKGROUND

Substrate parasitic leakage and voltage are challenges when devices are integrated into or on a same integrated circuit (IC) die. Various techniques have been developed to address such leakage and voltage. However, challenges may still persist, particularly for certain applications, such as high voltage applications.

### SUMMARY

This Summary is provided to introduce a brief selection of disclosed concepts in a simplified form that are further described below in the Detailed Description including the drawings provided. Various disclosed devices and methods may be beneficially applied to semiconductor substrates implementing junction isolation between devices. While such embodiments may be expected to increase an operating voltage before breakdown of a junction occurs, no particular result is a requirement unless explicitly recited in a particular claim.

An example described herein is a semiconductor device. The semiconductor device includes an epitaxial layer, a buried layer, a deep well, a drift well, a contact well, and a contact region. The epitaxial layer has a first conductivity type. The epitaxial layer is over a semiconductor substrate. The buried layer has a second conductivity type opposite from the first conductivity type. The buried layer is spaced apart from a top surface of the epitaxial layer. The deep well has the second conductivity type. The deep well extends in the epitaxial layer and touches the buried layer. The deep well laterally encircles an active area in the epitaxial layer over the buried layer. The drift well has the second conductivity type. The drift well extends in the epitaxial layer to a first depth. The drift well extends laterally from the deep well towards the active area. The contact well has the second conductivity type. The contact well extends in the epitaxial layer to a second greater depth and touching the drift well. The contact region has the second conductivity type. The contact region extends in the contact well.

Another example is an integrated circuit. The integrated circuit includes a transistor and a field plate. The transistor is in an active area in a semiconductor substrate. The transistor includes a source region in the semiconductor substrate, a drain region in the semiconductor substrate, and a gate electrode over the semiconductor substrate. The semiconductor substrate includes a buried layer, a deep well, and a drift well. The source region and the drain region are over the buried layer. The deep well extends to the buried layer. The deep well laterally encircles the active area. The drift well extends laterally from the deep well and to the drain region. The buried layer, the deep well, the drift well, and the drain region are doped by respective dopants having a same conductivity type. The field plate is over the semiconductor substrate and over the drift well. The field plate is laterally between the deep well and the drain region.

A further example is a method of forming a semiconductor device. A buried layer is formed in a semiconductor substrate. The buried layer has a first conductivity type. An epitaxial layer is formed over the semiconductor substrate. The epitaxial layer has a second conductivity type opposite from the first conductivity type. The buried layer is spaced apart from a top surface of the epitaxial layer. A deep well is formed extending in the epitaxial layer and touching the buried layer. The deep well laterally encircles an active area in the epitaxial layer over the buried layer. The deep well has the first conductivity type. A drift well is formed extending in the epitaxial layer. The drift well extends laterally from the deep well toward the active area. The drift well has the first conductivity type. A contact well is formed extending in the epitaxial layer and touching the drift well. The contact well has the first conductivity type. A contact region is formed extending in the epitaxial layer and in the contact well. The contact region has the first conductivity type.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross-sectional view of a semiconductor device according to some examples.

FIG. 2 is a cross-sectional view of another semiconductor device according to some examples.

FIG. 3 is a layout view of various components of the semiconductor devices of FIGS. 1 and 2.

FIG. 4 is a cross-sectional view of a semiconductor device according to some examples.

FIG. 5 is a chart illustrating a voltage curve of a contact well and a voltage curve of a junction isolation tank according to an example.

FIG. 6 is a chart illustrating an effect of biasing a junction isolation field plate in the semiconductor device of FIG. 4 according to some examples.

FIG. 7 is a cross-sectional view of a semiconductor device according to some examples.

FIGS. 8, 9, and 10 are respective circuit schematics of an integrated circuit (IC) in which a semi-floating junction isolation tank is implemented according to some examples.

FIGS. 11, 12, 13, 14, 15, 16, 17, 18, and 19 are cross-sectional views of the semiconductor device of FIG. 4 at various stages of manufacturing according to an example method.

FIGS. 20, 21, 22, 23, 24, 25, and 26 are cross-sectional views of a semiconductor device (like in FIG. 4) with the junction isolation tank connection mechanism of FIG. 2 at various stages of manufacturing according to an example method.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations. In the following discussion, doping levels may be described in quantitative and/or qualitative terms, wherein a doping level less than 1×10¹⁶ cm⁻³ is lightly doped, a doping level between 1×10¹⁶ cm⁻³ and 1×10¹⁸ cm ³ is moderately doped, a doping level between 1×10¹⁸ cm⁻³ and 1×10²⁰ cm ³ is heavily doped, and a doping level above 1×10²⁰ cm⁻³ is very heavily doped. A doping level at the boundaries of these ranges may be referred to qualitatively by either term referring to the higher or lower range.

The present disclosure relates generally, but not exclusively, to semi-floating junction isolation in a semiconductor substrate. In some examples, a buried layer and a deep well form a junction isolation tank in a semiconductor substrate. The deep well encircles an active area in the semiconductor substrate that is over the buried layer. A device, such as a transistor or diode, may be formed in the active area. A drift well extends from the deep well and touches a contact well. A contact region is in the contact well. The contact region, in some examples, may be a cathode terminal of a diode or a drain terminal of a transistor. In operation, in a first regime, the junction isolation tank may be electrically connected to the contact region through the drift well, which may allow a voltage of the junction isolation tank to follow a voltage of the contact region. In another regime, pinch-off occurs in the drift well such that the junction isolation tank may be electrically floating from the contact region. Such operation permits a voltage of the contact region to be increased before breakdown of the junction formed by the junction isolation tank and the semiconductor substrate inside the junction isolation tank. Other benefits and advantages can be achieved.

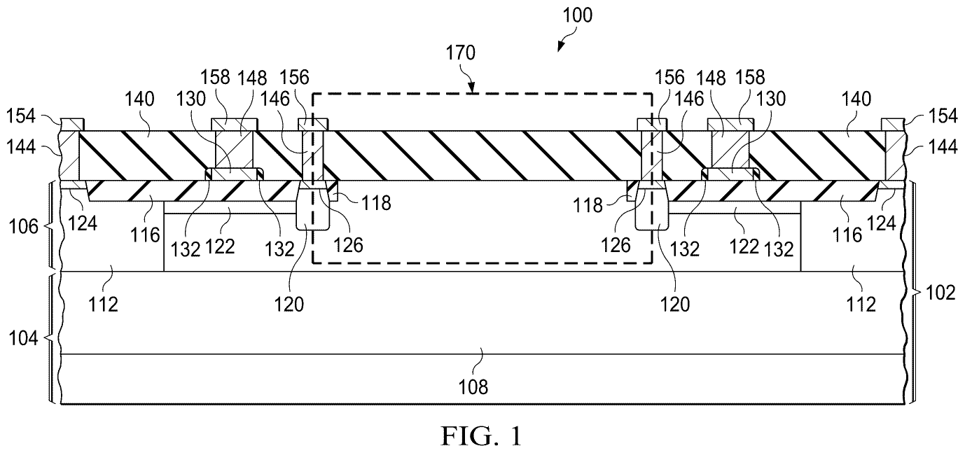

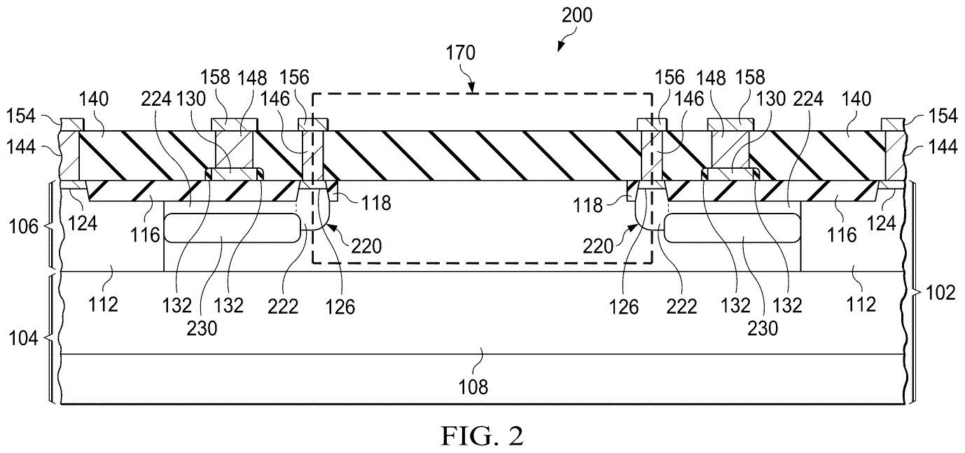

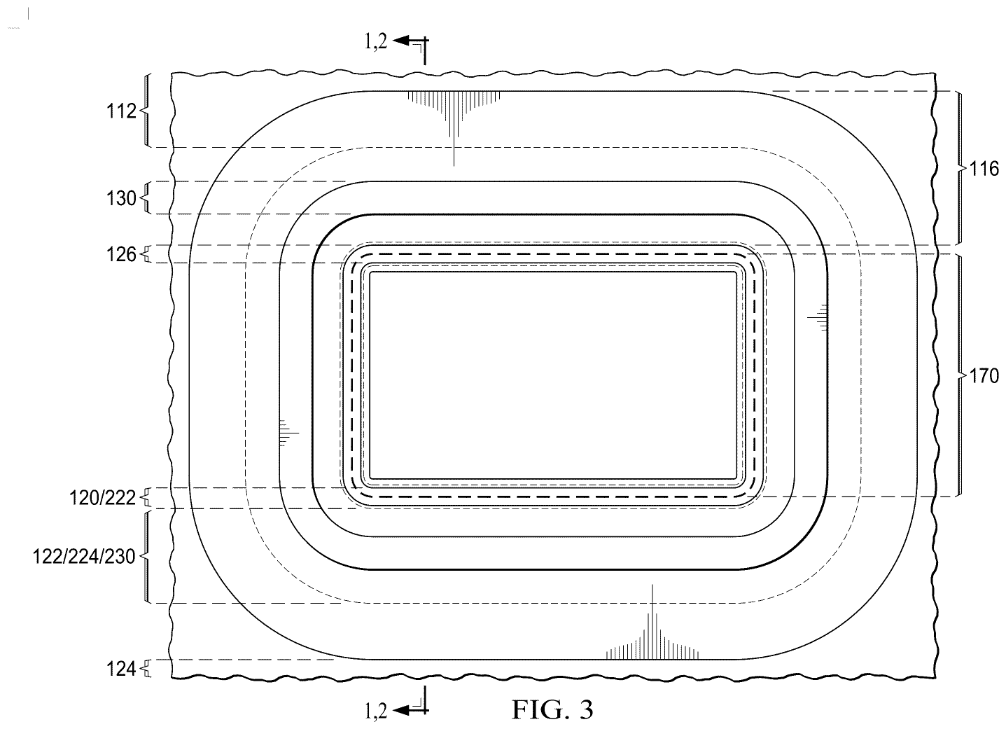

FIGS. 1 and 2 are respective cross-sectional views of semiconductor devices 100, 200 according to some examples. FIG. 3 generally shows a layout view of various components of the semiconductor devices 100, 200 of FIGS. 1 and 2. FIG. 3 shows a cross-section location that corresponds to the cross-sectional views illustrated in FIGS. 1 and 2. The semiconductor devices 100, 200, as illustrated in FIG. 3, may be in a colloquial lateral “racetrack” configuration.

The semiconductor devices 100, 200 of FIGS. 1 and 2 generally implement a junction isolation mechanism that includes a junction isolation tank (e.g., including a deep buried layer 108 and a deep well 112) in a semiconductor substrate. The junction isolation tank generally contains a portion of the semiconductor substrate in which a device (e.g., a diode, a transistor, etc.) is disposed. The junction isolation tank forms a p-n junction with the portion of the semiconductor substrate in which the device is disposed, which p-n junction permits isolation of the device from other portions of the semiconductor substrate.

In FIGS. 1 and 2, the respective junction isolation tanks are configured to be semi-floating during operation of a device in the portion of the semiconductor substrate encompassed by the junction isolation tank. The junction isolation tanks are not ohmically, electrically connected to another node or active component. As detailed subsequently, the junction isolation tanks may be electrically connected through a drift well (e.g., which may be a drift well portion) to another doped region of the device in a first regime. A junction isolation field plate is over the drift well, which may form a type of junction field effect transistor (JFET) connection through the drift well. In other regimes (e.g., second and third regimes described subsequently), the junction isolation tank is not electrically connected to that other doped region of the device. This type of connection and disconnection may permit the voltage of the junction isolation tank to increase, which may permit a breakdown voltage of a p-n junction between the semiconductor substrate and junction isolation tank to increase.

FIGS. 1 and 2 show a semiconductor substrate 102. The semiconductor substrate 102, in the illustrated examples, includes a semiconductor support (or handle) substrate 104 (or handle wafer) and an epitaxial layer 106. The semiconductor support substrate 104 may be a bulk semiconductor substrate, a semiconductor-on-insulator (SOI) substrate, or any other appropriate substrate. The epitaxial layer 106 is epitaxially grown on or over the semiconductor support substrate 104. The epitaxial layer 106 may be or include silicon (Si), silicon germanium (SiGe), gallium arsenide (GaAs), gallium nitride (GaN), the like, or a combination thereof. In some examples, the semiconductor support substrate 104 is or includes a silicon substrate (which may be singulated from a bulk silicon wafer at the conclusion of semiconductor processing), and the epitaxial layer 106 is or includes a layer of silicon. In some examples, the epitaxial layer 106 may be omitted, and a semiconductor material of the semiconductor substrate 102 (e.g., in or on which devices are formed) may be or include silicon (Si), silicon germanium (SiGe), gallium arsenide (GaAs), the like, or a combination thereof. The semiconductor substrate 102 has a top major surface in and/or on which devices (e.g., diodes, transistors, etc.) are generally disposed and formed.

Various doped buried layers, wells, and doped regions are in the semiconductor substrate 102. Generally, with reference to FIG. 1, a deep buried layer 108 (e.g., a doped buried layer), a deep well 112, a drift well 122, a contact well 120, and contact regions 124, 126 (e.g., doped regions) are in the semiconductor substrate 102. The epitaxial layer 106 (or more generally, the semiconductor substrate 102) is doped with a dopant of a first conductivity type (e.g., a p-type dopant). The deep buried layer 108, the deep well 112, the drift well 122, the contact well 120, and the contact regions 124, 126 are doped with respective dopants of a same second conductivity type (e.g., an n-type dopant) that is opposite or counter from the first conductivity type. Generally, with reference to FIG. 2, a deep buried layer 108, a deep well 112, a well 220 (which includes a drift well portion 224 and a well portion 222), a buried layer 230 (e.g., a doped buried layer), and contact regions 124, 126 are in the semiconductor substrate 102. The epitaxial layer 106 (or more generally, the semiconductor substrate 102) and the buried layer 230 are doped with respective dopants of a first conductivity type (e.g., a p-type dopant). The deep buried layer 108, the deep well 112, the well 220, and the contact regions 124, 126 are doped with respective dopants of a same second conductivity type (e.g., an n-type dopant) that is opposite or counter from the first conductivity type.

In both FIGS. 1 and 2, the respective junction isolation tanks include the deep buried layer 108 and the deep well 112. As illustrated, the junction isolation tanks may also include the contact region 124, and in other examples, the contact region 124 may be omitted.

The counter or opposite doping of the junction isolation tank (e.g., the deep buried layer 108 and the deep well 112) from the epitaxial layer 106 (or more generally, the semiconductor substrate 102) forms a p-n junction between the junction isolation tank and the epitaxial layer 106 within the junction isolation tank.

The deep buried layer 108 is disposed in the semiconductor substrate 102 (e.g., the semiconductor support substrate 104). The deep buried layer 108 extends from an interface between the semiconductor support substrate 104 and the epitaxial layer 106 to a depth in the semiconductor support substrate 104. Although not illustrated in FIG. 3, the deep buried layer 108 extends laterally throughout the layout shown in FIG. 3. As used herein, a buried layer is a layer in a semiconductor substrate (e.g., the semiconductor substrate 102) and with characteristics, such as conductivity type or dopant concentration, that is spaced apart from a top surface of the semiconductor substrate (e.g., the top major surface of the epitaxial layer 106) by a spacing layer or material that has a significantly different characteristic, such as different conductivity type or different dopant concentration. For example a buried layer may be an n-doped diffusion layer spaced apart from the top surface of the semiconductor substrate by an n-type or p-type in situ doped epitaxial layer.

The deep well 112 is disposed in the semiconductor substrate 102 (e.g., in the epitaxial layer 106, as illustrated). The deep well 112 extends from proximate the top major surface of the semiconductor substrate 102 to and contacting the deep buried layer 108. The deep well 112 is along a periphery of the illustrated layout of FIG. 3.

The contact region 124 is disposed in the semiconductor substrate 102 (e.g., in the epitaxial layer 106, as illustrated). The contact region 124 is in the deep well 112 and extends from the top major surface of the semiconductor substrate 102 into the semiconductor substrate 102. The contact region 124 may be omitted in other examples.

With the deep well 112 extending to and contacting the deep buried layer 108 and with the deep buried layer 108 extending laterally throughout the layout of FIG. 3, the deep well 112 and the deep buried layer 108 form a “bathtub” (e.g., the junction isolation tank) in which a device may be formed. The deep well 112 and deep buried layer 108 generally contain and permit isolation of a portion of the semiconductor substrate 102 in which the device is formed.

Dielectric isolation structures 116, 118 are disposed at the top major surface of the semiconductor substrate 102 and extend into the semiconductor substrate 102 (e.g., in the epitaxial layer 106, as illustrated). The dielectric isolation structures 116, 118 may be or include any appropriate dielectric or isolation material. In some examples, the dielectric isolation structures 116, 118 are shallow trench isolations (STIs), and in some examples, the dielectric isolation structures 116, 118 may be other dielectric isolation structures, such as field oxide structures, local oxidation of silicon (LOCOS) structures, stepped gate dielectric structures, or the like. The dielectric isolation structure 116 is disposed at least partially laterally within the deep well 112 and extend laterally away from the deep well 112 interior to the junction isolation tank. The dielectric isolation structure 116 extends laterally from the contact region 124.

Referring to FIGS. 1 and 3, the contact well 120 is disposed in the semiconductor substrate 102 (e.g., in the epitaxial layer 106, as illustrated). The contact well 120 extends from proximate the top major surface of the semiconductor substrate 102 to a depth in the epitaxial layer 106. The depth to which the contact well 120 extends is less than a depth of a top of the deep buried layer 108, and hence, the contact well 120 does not extend as deep as the deep well 112. A portion of the epitaxial layer 106 that is doped opposite from the contact well 120 and the deep buried layer 108 is vertically between the contact well 120 and the deep buried layer 108. The contact well 120 is generally laterally between the dielectric isolation structure 116 and the dielectric isolation structure 118.

The contact region 126 is disposed in the semiconductor substrate 102 (e.g., in the epitaxial layer 106, as illustrated). The contact region 126 is in the contact well 120 and extends from the top major surface of the semiconductor substrate 102 into the semiconductor substrate 102. The dielectric isolation structure 116 extends laterally from the contact region 124 to the contact region 126. The contact region 126 is laterally between the dielectric isolation structures 116, 118.

The drift well 122 is disposed in the semiconductor substrate 102 (e.g., in the epitaxial layer 106, as illustrated). The drift well 122 is under the dielectric isolation structure 116. The drift well 122 extends laterally from the deep well 112 to the contact well 120. The drift well 122 extends to a depth in the epitaxial layer 106 that is shallower than the depth to which the contact well 120 extends. The drift well 122 may be considered a shallow well. As shown in FIG. 3, the deep well 112 laterally encircles the drift well 122, which laterally encircles the contact well 120.

Respective concentrations of the dopants of the deep buried layer 108, the deep well 112, the drift well 122, and the contact well 120 are greater than the concentration of the dopant of the epitaxial layer 106. A concentration of the dopant of the contact region 124 is greater than a concentration of the dopant of the deep well 112, and a concentration of the dopant of the contact region 126 is greater than a concentration of the dopant of the contact well 120.

In some examples, the epitaxial layer 106 may be p-doped in situ with a p-type dopant (e.g., boron) at a concentration in a range from about 1×10¹⁴ cm⁻³ to about 5×10¹⁵ cm⁻³, e.g., lightly doped. In some examples, the deep buried layer 108 may be an n-type layer doped with an n-type dopant (e.g., phosphorous and/or arsenic) at a concentration in a range from about 1×10¹⁷ cm⁻³ to about 8×10¹⁸ cm⁻³, e.g., moderately to heavily doped. In some examples, the deep well 112 may be an n-well doped with an n-type dopant at a concentration in a range from about 1×10¹⁷ cm⁻³ to about 2×10²⁰ cm⁻³, e.g., moderately to very heavily doped. In some examples, the contact well 120 may be an n-well doped with an n-type dopant at a concentration in a range from about 1×10¹⁷ cm⁻³ to about 2×10²⁰ cm⁻³, e.g., moderately to very heavily doped. In some examples, the drift well 122 may be an n-well doped with an n-type dopant at a concentration in a range from about 1×10¹⁷ cm⁻³ to about 2×10²⁰ cm⁻³, e.g., moderately to very heavily doped. In some examples, the contact regions 124, 126 may be n-doped with an n-type dopant at a concentration in a range from about 1×10²⁰ cm⁻³ to about 3×10²¹ cm⁻³, e.g., very heavily doped.

Referring to FIGS. 2 and 3, the well 220 is disposed in the semiconductor substrate 102 (e.g., in the epitaxial layer 106, as illustrated). The well 220 extends from proximate the top major surface of the semiconductor substrate 102 to a depth in the epitaxial layer 106. The depth to which the well 220 extends is less than a depth of a top of the deep buried layer 108, and hence, the well 220 does not extend as deep as the deep well 112. The well 220 is partially under the dielectric isolation structure 116. The well 220 laterally extends from the deep well 112 to the dielectric isolation structure 118.

The buried layer 230 is disposed in the semiconductor substrate 102 (e.g., in the epitaxial layer 106, as illustrated). The buried layer 230 is under the dielectric isolation structure 116. The buried layer 230 overlaps and dominates a lower portion of the well 220 that underlies the dielectric isolation structure 116. A concentration of the dopant of the buried layer 230 is greater than a concentration of the dopant of the well 220.

The overlap of the buried layer 230 with the well 220 results in a well portion 222 and a drift well portion 224 of the well 220. The drift well portion 224 extends laterally from the deep well 112 to the well portion 222 (similar to the drift well 122 extending laterally from the deep well 112 to the contact well 120 in FIG. 1). The drift well portion 224 is over the buried layer 230. The drift well portion 224 and the buried layer 230 extend laterally from the deep well 112 and laterally encircles the well portion 222. As shown in FIG. 3, the deep well 112 laterally encircles the drift well portion 224, which laterally encircles the well portion 222. The deep well 112 also laterally encircles the buried layer 230.

The contact region 126 is in the well portion 222. A portion of the epitaxial layer 106 that is doped opposite from the well 220 and the deep buried layer 108 is vertically between the well portion 222 and the deep buried layer 108.

Respective concentrations of the dopants of the deep buried layer 108, the deep well 112, the well 220 (including the drift well portion 224 and the well portion 222) are greater than the concentration of the dopant of the epitaxial layer 106. A concentration of the dopant of the contact region 124 is greater than a concentration of the dopant of the deep well 112, and a concentration of the dopant of the contact region 126 is greater than a concentration of the dopant of the well 220 (e.g., the well portion 222). A concentration of the buried layer 230 is greater than the concentration of the dopant of the epitaxial layer 106.

In some examples, the epitaxial layer 106 may be p-doped in situ with a p-type dopant (e.g., boron) at a concentration in a range from about 1×10¹⁴ cm⁻³ to about 5×10¹⁵ cm⁻³, e.g., lightly doped. In some examples, the deep buried layer 108 may be an n-type layer doped with an n-type dopant (e.g., phosphorous and/or arsenic) at a concentration in a range from about 1×10¹⁷ cm⁻³ to about 8×10¹⁸ cm⁻³, e.g., moderately to heavily doped. In some examples, the deep well 112 may be an n-well doped with an n-type dopant at a concentration in a range from about 1×10¹⁷ cm⁻³ to about 2×10²⁰ cm⁻³, e.g., moderately to heavily doped. In some examples, the well 220 (e.g., including the drift well portion 224 and the well portion 222) may be an n-well doped with an n-type dopant at a concentration in a range from about 1×10¹⁷ cm⁻³ to about 2×10²⁰ cm⁻³, e.g., moderately to very heavily doped. In some examples, the buried layer 230 may be p-doped with a p-type dopant at a concentration in a range from about 5×10¹⁷ cm⁻³ to about 7×10²⁰ cm⁻³, e.g., moderately to very heavily doped. In some examples, the contact regions 124, 126 may be n-doped with an n-type dopant at a concentration in a range from about 1×10²⁰ cm⁻³ to about 3×10²¹ cm⁻³, e.g., very heavily doped.

Referring to FIGS. 1 and 2, as mentioned, in some examples, the epitaxial layer 106 may be omitted. In such examples, the deep buried layer 108 may be implanted at a depth in the semiconductor substrate 102, and a well may be implanted in the semiconductor substrate 102 extending from a top major surface of the semiconductor substrate 102 to a depth to or above the deep buried layer 108. The well maybe counter-doped from the deep buried layer 108 like described with respect to the epitaxial layer 106.

A junction isolation field plate 130 is over and on the dielectric isolation structure 116 and over the drift well 122 (in FIG. 1) or drift well portion 224 (in FIG. 2). The junction isolation field plate 130 is or includes a conductive material. In some examples, the junction isolation field plate 130 is or includes doped polycrystalline silicon (polysilicon). In some examples, the junction isolation field plate 130 may be or include a metal. The junction isolation field plate 130, as illustrated, may be at a gate level and may be formed by processes for forming a gate electrode for another device. The junction isolation field plate 130 may also be considered a gate electrode. In other examples, the field plate may be in a metal layer over the semiconductor substrate 102 (e.g., in or over one or more dielectric layers). Dielectric spacers 132 are on respective sidewalls of the junction isolation field plate 130 and may be any appropriate dielectric material, such as silicon nitride, silicon oxynitride, silicon carbon nitride, the like, or a combination thereof.

A dielectric layer 140 is disposed on or over the semiconductor substrate 102. Such a dielectric layer is sometimes referred to as a pre-metal dielectric layer. More specifically, the dielectric layer 140 is disposed on or over the dielectric isolation structures 116, 118, the junction isolation field plate 130, and the dielectric spacers 132. The dielectric layer 140 may include multiple dielectric layers. For example, the dielectric layer 140 may include an etch stop layer (e.g., silicon nitride (SiN) or the like) disposed conformally along surfaces of, e.g., the dielectric isolation structures 116, 118, the junction isolation field plate 130, and the dielectric spacers 132, and may include an inter-layer dielectric (e.g., an oxide or the like) disposed on the etch stop layer.

Metal contacts 144, 146, 148 are disposed through the dielectric layer 140 and contact the contact region 124, contact region 126, and junction isolation field plate 130, respectively. Each of the metal contacts 144, 146, 148 may include one or more barrier and/or adhesion layers (e.g., titanium nitride (TiN), tantalum nitride (TaN), the like, or a combination thereof) conformally in a respective opening through the dielectric layer 140, and may include a conductive fill material (e.g., a metal, such as tungsten (W), copper (Cu), a combination thereof, or the like) on and/or over the barrier and/or adhesion layer(s).

Metal lines 154, 156, 158 are disposed on and over the dielectric layer 140 and respective metal contacts 144, 146, 148. Each of the metal lines 154, 156, 158 may include one or more barrier and/or adhesion layers and a conductive fill material on and/or over the barrier and/or adhesion layer(s), like the metal contacts 144, 146, 148.

A device region 170 is generally shown in FIGS. 1, 2, and 3. The device region 170 is a region in which a device may be formed. The device region 170 may define an active area of the semiconductor substrate 102 in which a device may be formed, as illustrated by subsequent examples. Other structures of a device may be formed over the semiconductor substrate 102 in the device region 170, such as field plates, gate electrodes, or the like. The device region 170 is generally laterally interior to the contact well 120 or well portion 222. The device region 170 may include the contact well 120 or well portion 222 and may include the contact region 126.

The contact well 120 or well portion 222 generally laterally encircles the device region 170. The dielectric isolation structure 118 extends laterally from the contact region 126 into the device region 170 of the semiconductor substrate 102. As illustrated subsequently, the contact region 126 and contact well 120 or well portion 222 may form a portion of a device formed in the device region 170, such as a cathode region of a diode, a drain region of a transistor, or the like. Any device formed in the semiconductor substrate 102 (e.g., the epitaxial layer 106) in the device region 170 is contained within the junction isolation tank (e.g., the deep buried layer 108 and the deep well 112).

FIGS. 1 and 2 show different junction isolation tank connection mechanisms. A semiconductor device may implement any of the junction isolation tank connection mechanisms of FIGS. 1 and 2 and any other similar connection mechanism. The junction isolation tank connection mechanism of FIG. 1 includes the drift well 122, the contact well 120, and the junction isolation field plate 130. The junction isolation tank connection mechanism of FIG. 2 includes the drift well portion 224, the well portion 222, and the junction isolation field plate 130. These junction isolation tank connection mechanisms may provide for an electrical connection to the junction isolation tank under certain operating conditions (e.g., a certain operating regime) and may electrically disconnect the junction isolation tank in other operating regimes. The junction isolation tank connection mechanism of FIG. 1 may be more easily integrated with processing to form some devices, while the junction isolation tank connection mechanism of FIG. 2 may be more easily integrated with processing to form other devices. Additionally, in some examples, the buried layer 230 in FIG. 2 may permit improved tuning of a breakdown voltage.

The junction isolation tank (e.g., the deep well 112 and deep buried layer 108) may be configured to be semi-floating during operation of a device formed in the device region 170. The junction isolation tank may be ohmically electrically floating. In this context, “ohmically electrically floating” means the junction isolation tank is not directly conductively connected by an ohmic connection to an electrical potential node that could hold the junction isolation tank at a voltage of that electrical potential node. For example, the metal contacts 144 and metal lines 154 may not be ohmically electrically connected to another node or active component. In some examples, the metal contacts 144 and metal lines 154 are omitted, and no metal contact is to the contact region 124. In other examples (e.g., a non-floating implementation), the junction isolation tank may be ohmically, electrically connected to another node, such as in a circuit that controls a voltage of the junction isolation tank.

In operation, the junction isolation tank connection mechanism may operate in three regimes. In a first regime, the junction isolation tank is electrically connected to, in reference to FIG. 1, the contact well 120 and the contact region 126 through the drift well 122, and in reference to FIG. 2, the well portion 222 and the contact region 126 through the drift well portion 224. In the first regime, a voltage difference between the junction isolation field plate 130 and the contact region 126 is low such that the region under the junction isolation field plate 130 in the drift well 122 or drift well portion 224 is not depleted and is conductive. Hence, in the first regime, the voltage of the junction isolation tank is generally equal to the voltage of the contact region 126. In the second regime, the junction isolation tank becomes electrically disconnected from the contact region 126 and the contact well 120 or well portion 222. In the second regime, a voltage difference between the junction isolation field plate 130 and the contact region 126 is sufficiently high such that the region under the junction isolation field plate 130 in the drift well 122 or drift well portion 224 becomes depleted and pinch off occurs. In this second regime, the voltage of the junction isolation tank may remain substantially constant, while the voltage of the contact region 126 may vary. In a third regime, the junction isolation tank remains electrically disconnected from the contact region 126 and the contact well 120 or well portion 222, and the voltage difference between (i) the junction isolation tank and (ii) the contact region 124 and contact well 120 or well portion 222 becomes sufficiently large that leakage from the contact well 120 or well portion 222 to the deep buried layer 108 occurs (e.g., through the epitaxial layer 106). The leakage can cause the voltage of the junction isolation tank to generally follow the voltage of the contact region 126 and the contact well 120 or well portion 222. At a sufficiently large voltage of the contact region 126, breakdown may occur.

The electrical connection through the drift well 122 or drift well portion 224 in the first regime permits the voltage of the junction isolation tank to increase as the voltage of the contact region 126 increases. Further, the voltage of the junction isolation tank may increase due to leakage in the third regime. These voltage increases of the junction isolation tank may reduce a voltage drop across a p-n junction formed between the epitaxial layer 106 and the junction isolation tank. Hence, with a lower voltage drop across this p-n junction, breakdown of the p-n junction may occur at higher operating voltages (e.g., a higher voltage of the contact region 126).

The junction isolation field plate 130 may be tuned to adjust the voltage difference that causes the drift well 122 or drift well portion 224 to become depleted. The lateral position of the junction isolation field plate 130 between (i) the deep well 112 and (ii) the contact well 120 or well portion 222 may affect the electric field experienced by the drift well 122 or drift well portion 224 that causes depletion. Further, a lateral dimension (e.g., length) of the junction isolation field plate 130 in the cross-section indicated in FIG. 3 (and illustrated in FIGS. 1 and 2) may affect the electric field. Also, the voltage or potential applied to the junction isolation field plate 130 may affect the electric field. Any one or more of these characteristics may be modified or tuned to control the transition from the first regime to the second regime.

Additionally, any device(s) formed in the device region 170 may operate at much more negative voltages than otherwise achievable. The semi-floating junction isolation tank may extend the ability of a circuit to be operated at more negative voltages while maintaining isolation from the semiconductor substrate outside of the junction isolation tank.

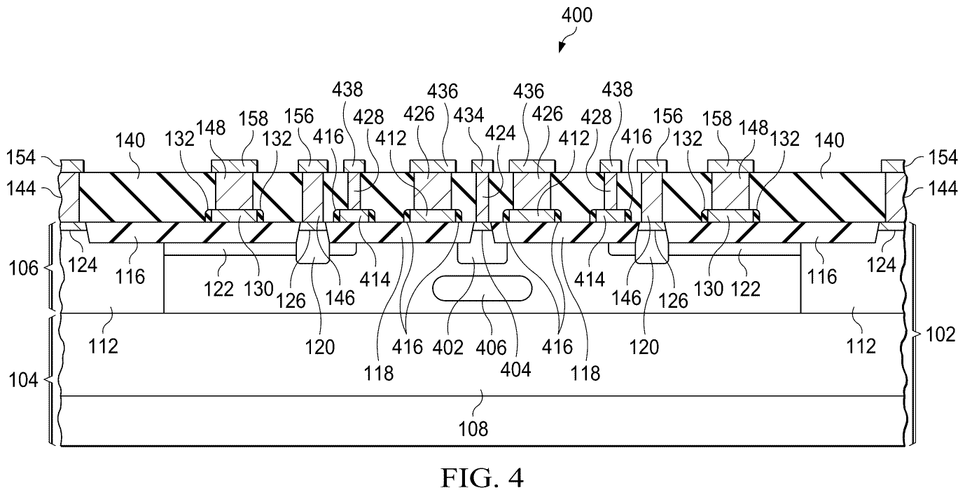

FIG. 4 is a cross-sectional view of a semiconductor device 400 according to some examples. The semiconductor device 400 includes a diode formed in the device region 170. The junction isolation tank connection mechanism illustrated in FIG. 4 is what is illustrated in and described above with respect to FIG. 1. In other examples, the junction isolation tank connection mechanism of FIG. 2 may be implemented. Like components described above are indicated by like reference numbers, and description of such components is omitted here to avoid repetition.

In addition to the doped layers, wells, and regions of FIG. 1 (or of FIG. 2 in other implementations), an anode well 402, an anode terminal 404 (e.g., a doped region), and a buried layer 406 (e.g., a doped layer) are in the semiconductor substrate 102. The anode well 402, anode terminal 404, buried layer 406, and epitaxial layer 106 (or more generally, the semiconductor substrate 102) are doped with respective dopants of a same first conductivity type (e.g., a p-type dopant). Other doped layers, wells, and regions of FIG. 1 (or of FIG. 2 in other implementations) are as described above.

The anode well 402, the anode terminal 404, and the buried layer 406 are in the semiconductor substrate 102 (e.g., in the epitaxial layer 106, as illustrated). The anode well 402 extends from proximate the top major surface of the semiconductor substrate 102 to a depth in the epitaxial layer 106. The anode well 402 is generally laterally encircled by the dielectric isolation structure 118. The anode terminal 404 is in the anode well 402 and extends from the top major surface of the semiconductor substrate 102 into the semiconductor substrate 102. The dielectric isolation structure 118 laterally encircles the anode terminal 404. The dielectric isolation structure 118 laterally extends from the contact region 126 to the anode terminal 404. The buried layer 406 is under the anode well 402, and more specifically, between the anode well 402 and the deep buried layer 108. In the illustrated example, the buried layer 406 extends laterally beyond the anode well 402, and in other examples, the buried layer 406 does not extend laterally beyond the anode well 402.

Respective concentrations of the dopant of the anode well 402 and the buried layer 406 are greater than a concentration of a dopant of the epitaxial layer 106. A concentration of the dopant of the anode terminal 404 is greater than a concentration of the dopant of the anode well 402.

In some examples, the anode well 402 may be a p-well doped with a p-type dopant at a concentration in a range from about 1×10¹⁷ cm⁻³ to about 2×10²⁰ cm⁻³, e.g., moderately to very heavily doped. In some examples, the anode terminal 404 may be p-doped with a p-type dopant at a concentration in a range from about 1×10²⁰ cm⁻³ to about 3×10²¹ cm⁻³, e.g., very heavily doped. In some examples, the buried layer 406 may be p-doped with a p-type dopant at a concentration in a range from about 5×10¹⁷ cm⁻³ to about 7×10²⁰ cm⁻³, e.g., moderately to very heavily doped.

In the semiconductor device 400 of FIG. 4, the contact well 120 is a cathode well, and the contact region 126 is a cathode terminal. As shown, the drift well 122 may extend from the contact well 120 laterally towards the anode well 402 underlying the dielectric isolation structure 118.

The semiconductor device 400 includes an anode field plate 412 and a cathode field plate 414. The anode field plate 412 is over and on the dielectric isolation structure 118 proximate the anode well 402 and the anode terminal 404. The cathode field plate 414 is over and on the dielectric isolation structure 118 proximate the contact well 120 and the contact region 126. The anode field plate 412 and the cathode field plate 414 are laterally between the anode terminal 404 and the contact region 126 (e.g., the cathode terminal). The field plates 412, 414 are or include a conductive material. In some examples, the field plates 412, 414 are or include doped polycrystalline silicon (polysilicon). In some examples, the field plates 412, 414 may be or include a metal. The field plates 412, 414, as illustrated, may be at a gate level and may be formed by processes for forming a gate electrode for another device. The field plates 412, 414 may also be considered a gate electrode. In other examples, the field plates may be in a metal layer over the semiconductor substrate 102 (e.g., in or over one or more dielectric layers). The field plates 412, 414 may be like the junction isolation field plate 130. Dielectric spacers 416 are on respective sidewalls of the field plates 412, 414 and may be any appropriate dielectric material, such as silicon nitride, silicon oxynitride, silicon carbon nitride, the like, or a combination thereof. Examples may include multiple, separate anode field plates, each of which may have an independent voltage applied. Also, examples may include multiple, separate cathode field plates, each of which may have an independent voltage applied. An arbitrary number of field plates may be used to control the electrostatic behavior in the active device area resulting in higher break down voltage, lower on-resistance, and/or lower parasitic capacitance.

Metal contacts 424, 426, 428 are disposed through the dielectric layer 140 and contact the anode terminal 404, anode field plate 412, and cathode field plate 414, respectively. Metal lines 434, 436, 438 are disposed on and over the dielectric layer 140 and respective metal contacts 424, 426, 428. The metal contacts 424, 426, 428 may be like the metal contacts 144, 146, 148 described above. The metal lines 434, 436, 438 may be like the metal lines 154, 156, 158 described above.

In some examples, the anode terminal 404 and the anode field plate 412 are ohmically, electrically connected together (e.g., via the metal contacts 424, 426, the metal lines 434, 436, and other metal lines and/or metal vias over the dielectric layer 140), and the contact region 126 (e.g., cathode terminal) and the cathode field plate 414 are ohmically, electrically connected together (e.g., via the metal contacts 146, 428, the metal lines 156, 438, and other metal lines and/or metal vias over the dielectric layer 140). In some examples, the anode terminal 404 and the anode field plate 412 are ohmically, electrically connected to a ground node. The field plates 412, 414 may control the electric fields in the diode. The field plates 412, 414 may cause the potential in the semiconductor substrate 102 to be distributed more, which may improve a breakdown voltage. The field plates 412, 414 may cause an impact ionization peak to be relatively deep in the semiconductor substrate 102, which may be far from any interface between the semiconductor material of the semiconductor substrate 102 and a dielectric material (e.g., in the dielectric isolation structure 118). The impact ionization peak being relatively deep may result in a low channel hot carrier risk in the diode. In other examples, the field plates 412, 414 may be omitted.

The junction isolation field plate 130 may be ohmically, electrically connected to various nodes to control the electric field in the drift well 122 or drift well portion 224, which may control when depletion and pinch-off occurs. In some examples, the junction isolation field plate 130, the anode terminal 404, and the anode field plate 412 are ohmically, electrically connected together (e.g., via the metal contacts 148, 424, 426, the metal lines 158, 434, 436, and other metal lines and/or metal vias over the dielectric layer 140). In further examples, the junction isolation field plate 130, the anode terminal 404, and the anode field plate 412 are ohmically, electrically connected to a ground node. In other examples, the junction isolation field plate 130 may be ohmically, electrically connected to another node that may control a voltage applied to the junction isolation field plate 130, which may be independent of other voltages of the semiconductor device 400. The junction isolation tank (e.g., the deep well 112 and deep buried layer 108) is semi-floating as described previously.

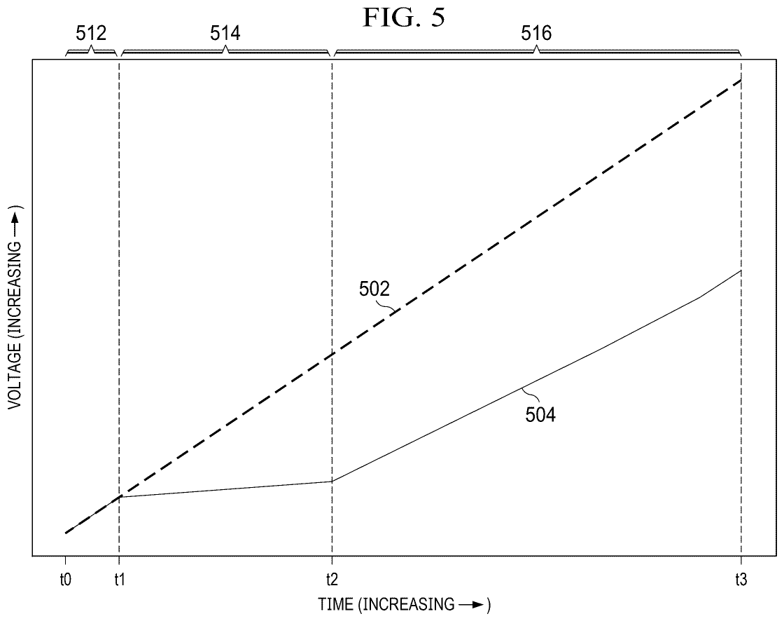

FIG. 5 is a chart illustrating a voltage curve 502 of the contact region 126 (e.g., a cathode terminal) and a voltage curve 504 of the junction isolation tank (e.g., the deep well 112 and deep buried layer 108) according to an example. In this example, which implements the semiconductor device 400 of FIG. 4, the junction isolation field plate 130, the anode terminal 404, and the anode field plate 412 are ohmically, electrically connected to a ground node, and the contact region 126 and the cathode field plate 414 are ohmically, electrically connected together.

The voltage curve 502 of the contact region 126 (e.g., a cathode terminal) increases linearly from time t0 to time t3. A first regime 512 is from time t0 to time t1. In the first regime 512, the junction isolation tank is electrically connected to the contact well 120 and the contact region 126 through the drift well 122. A voltage difference between the junction isolation field plate 130 and the contact region 126 is low such that the region under the junction isolation field plate 130 in the drift well 122 is not depleted and is conductive. Hence, in the first regime 512, the voltage curve 504 of the junction isolation tank is generally equal to the voltage curve 502 of the contact region 126.

A second regime 514 is from time t1 to time t2. In the second regime 514, the junction isolation tank becomes electrically disconnected from the contact region 126 and the contact well 120. A voltage difference between the junction isolation field plate 130 and the contact region 126 is sufficiently high such that the region under the junction isolation field plate 130 in the drift well 122 becomes depleted and pinch off occurs. The voltage curve 504 of the junction isolation tank remains substantially constant, while the voltage curve 502 of the contact region 126 continues to linearly increase.

A third regime 516 is from time t2 to time t3. In the third regime 516, the junction isolation tank remains electrically disconnected from the contact region 126 and the contact well 120, and the voltage difference between (i) the junction isolation tank and (ii) the contact region 126 and contact well 120 becomes sufficiently large that leakage from the contact well 120 to the deep buried layer 108 occurs. The leakage causes the voltage curve 504 of the junction isolation tank to generally follow the voltage curve 502 of the contact region 126. At a sufficiently large voltage of the contact region 126 at time t3, breakdown occurs.

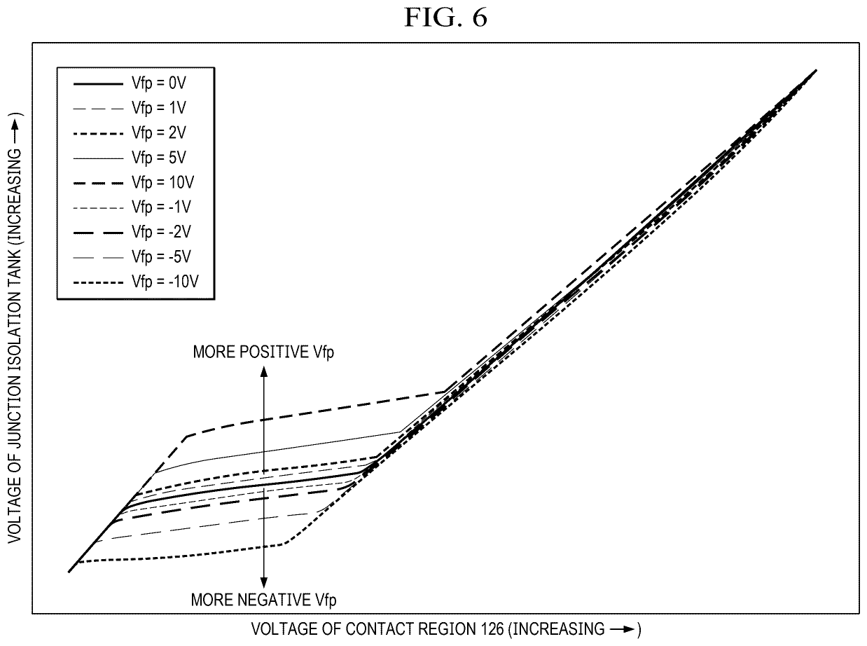

FIG. 6 is a chart illustrating an effect of biasing the junction isolation field plate 130 in the semiconductor device 400 of FIG. 4 according to some examples. In this example, the anode terminal 404 and the anode field plate 412 are ohmically, electrically connected to a ground node, and the contact region 126 and the cathode field plate 414 are ohmically, electrically connected together. The voltage of the junction isolation field plate 130 is controlled independently. FIG. 6 shows voltage curves of the junction isolation tank at differing voltages of the junction isolation field plate 130 (Vfp) as a function of the voltage of the contact region 126 (e.g., a cathode region). As shown, a more negative voltage of the junction isolation field plate 130 (Vfp) results in depletion in the drift well 122 occurring at lower voltages of the junction isolation tank and the contact region 126, and a more positive voltage of the junction isolation field plate 130 (Vfp) results in depletion in the drift well 122 occurring at higher voltages of the junction isolation tank and the contact region 126. Hence, the voltage of the junction isolation tank may be controlled by the voltage of the junction isolation field plate 130. Also, breakdown voltage of the p-n junction between the epitaxial layer 106 and the junction isolation tank is independent of the voltage of the junction isolation field plate 130.

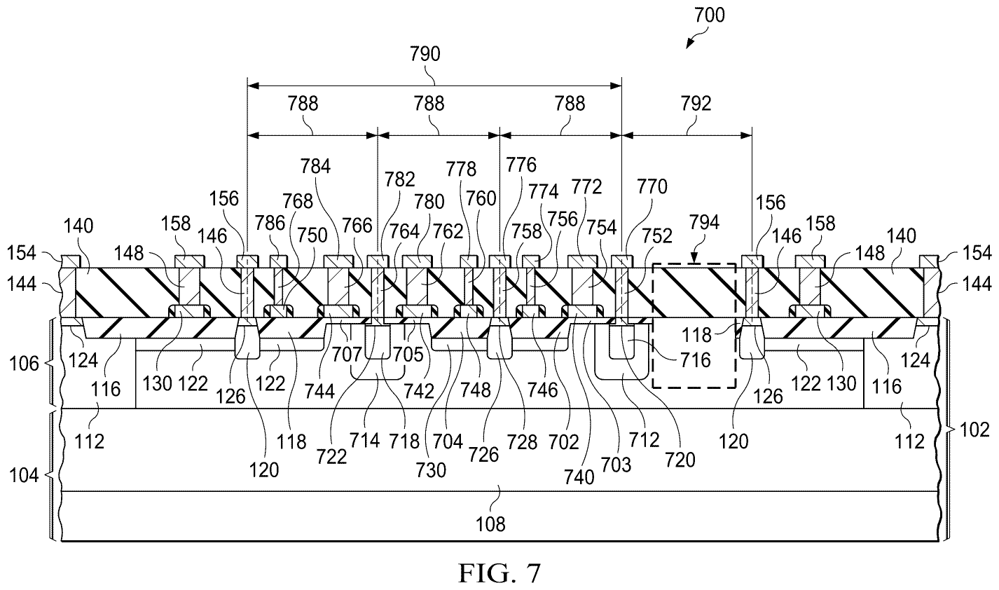

FIG. 7 is a cross-sectional view of a semiconductor device 700 according to some examples. The semiconductor device 700 includes a drain-extended metal-oxide-semiconductor (DeMOS) transistor (e.g., a drain-extended n-type metal-oxide-semiconductor (DeNMOS) transistor) formed in the device region 170. In some other examples, various doped regions and/or wells may be added or modified to implement a laterally-diffused metal-oxide-semiconductor (LDMOS) transistor in the device region 170. The junction isolation tank connection mechanism illustrated in FIG. 7 is what is illustrated in and described above with respect to FIG. 1. In other examples, the junction isolation tank connection mechanism of FIG. 2 may be implemented. Like components described above are indicated by like reference numbers, and description of such components is omitted here to avoid repetition.

The DeMOS in FIG. 7 is a multi-finger device that includes multiple source regions and multiple drain regions. Generally, half of the DeMOS is shown in FIG. 7. The other half may be mirrored around a midline of the DeMOS as described subsequently.

In addition to the doped layers, wells, and regions of FIG. 1 (or of FIG. 2 in other implementations), counter-source wells 712, 714, source wells 716, 718, source contact regions 720, 722, a drain well 726, a drain terminal 728, and a drift well 730 are in the semiconductor substrate 102. The counter-source wells 712, 714 and epitaxial layer 106 (or more generally, the semiconductor substrate 102) are doped with respective dopants of a same first conductivity type (e.g., a p-type dopant). The source wells 716, 718, the source contact regions 720, 722, the drain well 726, the drain terminal 728, and the drift well 730 are doped with respective dopants of a same second conductivity type (e.g., an n-type dopant) that is opposite or counter from the first conductivity type. Other doped layers, wells, and regions of FIG. 1 (or of FIG. 2 in other implementations) are as described above.

Dielectric isolation structures 702, 704 are disposed at the top major surface of the semiconductor substrate 102 and extend into the semiconductor substrate 102 (e.g., in the epitaxial layer 106, as illustrated). The dielectric isolation structures 702, 704 are like the dielectric isolation structures 116, 118. Gate dielectric layers 703, 705 are disposed at the top major surface of the semiconductor substrate 102 and extend laterally from the dielectric isolation structures 702, 704, respectively. Similarly, a gate dielectric layer 707 is disposed at the top major surface of the semiconductor substrate 102 and extends laterally from the dielectric isolation structure 118. The gate dielectric layers 703, 705, 707 may be or include any dielectric layer, such as silicon oxide, silicon nitride, or the like.

The counter-source wells 712, 714, source wells 716, 718, and source contact regions 720, 722 are in the semiconductor substrate 102 (e.g., in the epitaxial layer 106, as illustrated). The counter-source wells 712, 714 extend from proximate the top major surface of the semiconductor substrate 102 to a depth in the epitaxial layer 106. The counter-source well 712 is generally laterally encircled by and extends partially under the gate dielectric layer 703, and the counter-source well 714 is generally laterally between and extends partially under the gate dielectric layers 705, 707.

The source wells 716, 718 extend from proximate the top major surface of the semiconductor substrate 102 to a depth in the epitaxial layer 106 less than the depth of a respective counter-source well 712, 714. The source well 716 is in the counter-source well 712 and is generally laterally encircled by the gate dielectric layer 703. The source well 718 is in the counter-source well 714 and is generally laterally between the gate dielectric layers 705, 707.

The source contact region 720 is in the source well 716 and extends from the top major surface of the semiconductor substrate 102 into the semiconductor substrate 102. The gate dielectric layer 703 laterally encircles the source contact region 720. The source contact region 722 is in the source well 718 and extends from the top major surface of the semiconductor substrate 102 into the semiconductor substrate 102. The source contact region 722 is laterally between the gate dielectric layers 705, 707. The dielectric isolation structure 118 laterally extends from the contact region 126 to the gate dielectric layer 707, which laterally extends to the source contact region 722.

A concentration of the dopant of the counter-source wells 712, 714 is greater than a concentration of the dopant of the epitaxial layer 106. A concentration of the dopant of the source wells 716, 718 is greater than a concentration of the dopant of the counter-source wells 712, 714. A concentration of the dopant of the source contact regions 720, 722 is greater than a concentration of the dopant of the source wells 716, 718.

The drain well 726, the drain terminal 728, and the drift well 730 are in the semiconductor substrate 102 (e.g., in the epitaxial layer 106, as illustrated). The contact well 120 and the contact region 126 in this example are a drain well and a drain terminal, respectively. The drain well 726 extends from proximate the top major surface of the semiconductor substrate 102 to a depth in the epitaxial layer 106. The drain well 726 is generally laterally between the dielectric isolation structures 702, 704.

The drain terminal 728 is in the drain well 726 and extends from the top major surface of the semiconductor substrate 102 into the semiconductor substrate 102. The drain terminal 728 is laterally between the dielectric isolation structures 702, 704. The dielectric isolation structure 704 laterally extends from the drain terminal 728 to the gate dielectric layer 705, which laterally extends to the source contact region 722. The dielectric isolation structure 702 laterally extends from the drain terminal 728 to the gate dielectric layer 703, which laterally extends to the source contact region 720.

The drift well 730 laterally extends from the drain well 726 under the dielectric isolation structures 702, 704 (e.g., laterally from the drain well 726 towards the counter-source well 712 and laterally from the drain well 726 towards the counter-source well 714). The drift well 730 extends to a depth in the epitaxial layer 106 that is shallower than the depth to which the drain well 726 extends. The drift well 122 extends laterally from the contact well 120 under the dielectric isolation structure 118 (e.g., laterally from the contact well 120 towards the counter-source well 714).

A concentration of the dopant of the drain well 726 is greater than a concentration of the dopant of the epitaxial layer 106 and may be equal to a concentration of the dopant of the contact well 120. A concentration of the dopant of the drain terminal 728 is greater than a concentration of the dopant of the drain well 726 and may be equal to a concentration of the dopant of the contact region 126.

In some examples, the counter-source wells 712, 714 may be p-wells doped with a p-type dopant at a concentration in a range from about 1×10¹⁷ cm⁻³ to about 2×10²⁰ cm⁻³, e.g., moderately to very heavily doped. In some examples, the source wells 716, 718 and drain well 726 may be n-wells doped with an n-type dopant at a concentration in a range from about 5×10¹⁷ cm⁻³ to about 7×10²⁰ cm⁻³, e.g., moderately to very heavily doped. In some examples, the source contact regions 720, 722 and drain terminal 728 may be n-doped with an n-type dopant at a concentration in a range from about 1×10²⁰ cm⁻³ to about 3×10²¹ cm⁻³, e.g., very heavily doped. In some examples, the contact well 120 may be an n-well doped with an n-type dopant at a concentration in a range from about 1×10¹⁷ cm⁻³ to about 2×10²⁰ cm⁻³, e.g., moderately to very heavily doped.

The DeMOS includes gate electrodes 740, 742, 744 and drain field plates 746, 748, 750. The gate electrode 740 and the drain field plate 746 are laterally between the source well 716 and the drain well 726. The gate electrode 740 is over and on the gate dielectric layer 703, and may further be over and on the dielectric isolation structure 702. The gate electrode 740 is proximate the source contact region 720 and source well 716 and vertically overlaps a portion of the counter-source well 712. The drain field plate 746 is over and on the dielectric isolation structure 702, although in some examples, the drain field plate 746 is on a gate dielectric layer or other dielectric structure. The drain field plate 746 is proximate the drain terminal 728 and the drain well 726 and is over the drift well 730 underlying the dielectric isolation structure 702 extending from the drain well 726.

The gate electrode 742 and the drain field plate 748 are laterally between the source well 718 and the drain well 726. The gate electrode 742 is over and on the gate dielectric layer 703, and may further be over and on the dielectric isolation structure 704. The gate electrode 742 is proximate the source contact region 722 and source well 718 and vertically overlaps a portion of the counter-source well 714. The drain field plate 748 is over and on the dielectric isolation structure 704, although in some examples, the drain field plate 748 is on a gate dielectric layer or other dielectric structure. The drain field plate 748 is proximate the drain terminal 728 and the drain well 726 and is over the drift well 730 underlying the dielectric isolation structure 704 extending from the drain well 726.

The gate electrode 744 and the drain field plate 750 are laterally between the source well 718 and the contact well 120. The gate electrode 744 is over and on the gate dielectric layer 707, and may further be over and on the dielectric isolation structure 118. The gate electrode 744 is proximate the source contact region 722 and source well 718 and vertically overlaps a portion of the counter-source well 714. The drain field plate 750 is over and on the dielectric isolation structure 118, although in some examples, the drain field plate 748 is on a gate dielectric layer or other dielectric structure. The drain field plate 750 is proximate the contact region 126 (e.g., a drain terminal) and the contact well 120 and is over the drift well 122 underlying the dielectric isolation structure 118 extending from the contact well 120.

The gate electrodes 740, 742, 744 and drain field plates 746, 748, 750 are or include a conductive material. In some examples, the gate electrodes 740, 742, 744 and drain field plates 746, 748, 750 are or include doped polycrystalline silicon (polysilicon). In some examples, the gate electrodes 740, 742, 744 and drain field plates 746, 748, 750 may be or include a metal. In other examples, the drain field plates may be in a metal layer over the semiconductor substrate 102 (e.g., in or over one or more dielectric layers). The drain field plates 746, 748, 750 may increase a breakdown voltage. In some examples, the drain field plates 746, 748, 750 may be omitted. Dielectric spacers (not numbered) are on respective sidewalls of the gate electrodes 740, 742, 744 and drain field plates 746, 748, 750 and may be like the dielectric spacers 132.

Examples may include multiple, separate drain field plates (e.g., where one drain field plate is illustrated), each of which may have an independent voltage applied. An arbitrary number of field plates may be used to control the electrostatic behavior in the active device area resulting in higher break down voltage, lower on-resistance, and/or lower parasitic capacitance.

The dielectric layer 140 is further disposed on or over the dielectric isolation structures 702, 704, the gate electrodes 740, 742, 744, the drain field plates 746, 748, 750, and the dielectric spacers. Metal contacts 752, 754, 756, 758, 760, 762, 764, 766, 768 are disposed through the dielectric layer 140. The metal contact 752 contacts the source contact region 720.

The metal contact 754 contacts the gate electrode 740. The metal contact 756 contacts the drain field plate 746. The metal contact 758 contacts the drain terminal 728. The metal contact 760 contacts the drain field plate 748. The metal contact 762 contacts the gate electrode 742. The metal contact 764 contacts the source contact region 722. The metal contact 766 contacts the gate electrode 744. The metal contact 768 contacts the drain field plate 750. The metal contacts 752-768 are like the metal contacts 144, 146, 148. Metal lines 770, 772, 774, 776, 778, 780, 782, 784, 786 are disposed on and over the dielectric layer 140 and respective metal contacts 752, 754, 756, 758, 760, 762, 764, 766, 768. The metal lines 770-786 are like the metal lines 154, 156, 158.

In some examples, the source contact regions 720, 722 are ohmically, electrically connected together (e.g., through the metal contacts 752, 764, metal lines 770, 782, and other metal lines and/or metal vias over the dielectric layer 140). The drain terminal 728 and contact region 126 (e.g., a drain terminal) are ohmically, electrically connected together (e.g., through the metal contacts 758, 146, metal lines 776, 156, and other metal lines and/or metal vias over the dielectric layer 140). The gate electrodes 740, 742, 744 are ohmically, electrically connected together (e.g., through the metal contacts 754, 762, 766, metal lines 772, 780, 784, and other metal lines and/or metal vias over the dielectric layer 140). The drain field plates 746, 748, 750 are ohmically, electrically connected together (e.g., through the metal contacts 756, 760, 768, metal lines 774, 778, 786, and other metal lines and/or metal vias over the dielectric layer 140). The junction isolation field plate 130 may be ohmically, electrically connected to the source contact regions 720, 722 (e.g., through the metal contacts 148, 752, 764, metal lines 158, 770, 782, and other metal lines and/or metal vias over the dielectric layer 140) or may be ohmically, electrically connected to another node, which may have a voltage independent of any node of the DeMOS. The junction isolation tank (e.g., the contact region 124, deep well 112, and deep buried layer 108) is semi-floating as described previously.

Half-pitches 788 are from a center or midline of a source contact region 720, 722 to a neighboring drain terminal 728 or contact region 126. A first device half 790 is shown and includes three half-pitches 788. Any odd number of half-pitches 788 may be included in the first device half 790. A second device half 792 includes the components of the first device half 790 in a mirrored configuration (e.g., mirrored around a midline of the source contact region 720), although not specifically illustrated to avoid obscuring features of FIG. 7. The components of the second device half 792 are generally depicted by a second device half region 794.

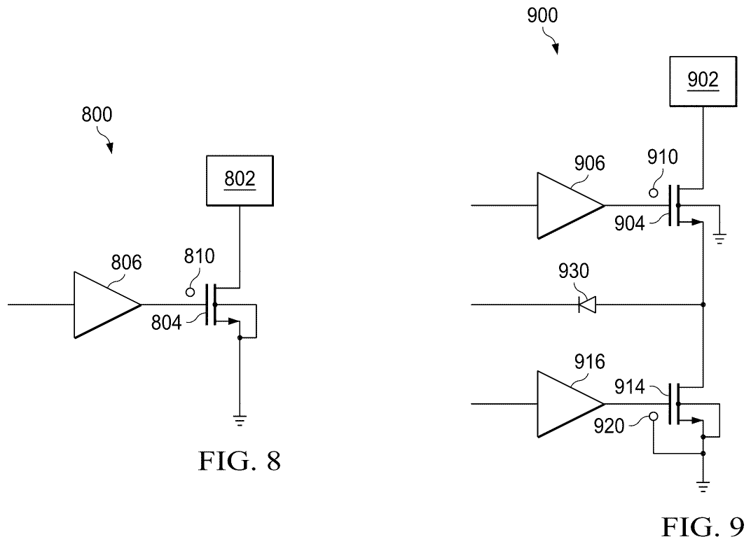

FIG. 8 is a circuit schematic 800 of an integrated circuit (IC) in which a semi-floating junction isolation tank is implemented according to some examples. The IC of the circuit schematic 800 may be on an IC die. The circuit schematic 800 includes a high side circuit 802 and a low side transistor 804. The high side circuit 802 may be or include any circuit or component thereof (e.g., one or more transistors). For example, the high side circuit 802 may be part of a power stage (such as in a buck converter), a high voltage switching circuit, or the like. The transistor 804 may be any transistor in a junction isolation tank 810, such as the DeMOS illustrated in FIG. 7, an LDMOS, or the like. The junction isolation tank 810 and junction isolation tank connection mechanism may be like described above with respect to FIG. 1 or FIG. 2.

A node of the high side circuit 802 is ohmically, electrically connected to a drain node of the transistor 804. A substrate (or body) node of the transistor 804 and a source node of the transistor 804 are ohmically, electrically connected to a ground node. A gate node of the transistor 804 is ohmically, electrically connected to an output node of a driver circuit 806. The junction isolation tank 810 is ohmically floating and is semi-floating (e.g., electrically connected to the drain node of the transistor 804 through a drift well in a first regime) as described above.

The high side circuit 802 may operate in a voltage range from 0 V to a breakdown voltage of the transistor 804. Hence, the voltage on the node of the high side circuit 802 ohmically, electrically connected to the drain node may be in a range from 0 V to the breakdown voltage.

Additionally, with the substrate (or body) node and source node both ohmically, electrically connected to a ground node and with the junction isolation tank 810 electrically connected to the drain node in the first regime, the voltage of the junction isolation tank 810 may be equal to or larger than the voltage of the substrate (or body) node. This may result in no unfavorable parasitic junction between the drain node, semiconductor substrate, and junction isolation tank (e.g., a parasitic NPN structure) turning on.

FIG. 9 is a circuit schematic 900 of an IC in which a semi-floating junction isolation tank is implemented according to some examples. The IC of the circuit schematic 900 may be on an IC die. The circuit schematic 900 includes a high side circuit 902 and cascaded low side transistors 904, 914. The high side circuit 902 may be or include any circuit or component thereof (e.g., one or more transistors). For example, the high side circuit 902 may be part of a power stage (such as in a buck converter), a high voltage switching circuit, or the like. The transistor 904 may be any transistor in a junction isolation tank 910, such as the DeMOS illustrated in FIG. 7, an LDMOS, or the like. The junction isolation tank 910 and junction isolation tank connection mechanism may be like described above with respect to FIG. 1 or FIG. 2. Similarly, the transistor 914 may be any transistor in another junction isolation tank 920, such as the DeMOS illustrated in FIG. 7, an LDMOS, or the like. The junction isolation tank 920 may be like described above with respect to FIG. 1 or FIG. 2.

A node of the high side circuit 902 is ohmically, electrically connected to a drain node of the transistor 904. A substrate (or body) node of the transistor 904 is ohmically, electrically connected to a ground node. A gate node of the transistor 904 is ohmically, electrically connected to an output node of a driver circuit 906. A source node of the transistor 904 is ohmically, electrically connected to a drain node of the transistor 914 and an input node of a diode 930. A substrate (or body) node of the transistor 914 and a source node of the transistor 914 are ohmically, electrically connected to a ground node. A gate node of the transistor 914 is ohmically, electrically connected to an output node of a driver circuit 916. The junction isolation tank 910 is ohmically floating and is semi-floating (e.g., electrically connected to the drain node of the transistor 904 through a drift well in a first regime) as described above. The junction isolation tank 920 is ohmically, electrically connected to a ground node. The junction isolation tanks 910, 920 may be separate tanks in a semiconductor substrate.

The high side circuit 902 may operate in a voltage range from 0 V to a breakdown voltage of the transistor 904. Hence, the voltage on the node of the high side circuit 902 ohmically, electrically connected to the drain node may be in a range from 0 V to the breakdown voltage.

The diode 930 generally illustrates a clamping mechanism that keeps the voltage on the source node of the transistor 904 and the drain node of the transistor 914 at or below a pinch off voltage of the drift well extending from the junction isolation tank 910. With the substrate (or body) node of the transistor 904 ohmically, electrically connected to a ground node, the voltage of the junction isolation tank 910 will be equal to or greater than the voltage of the substrate (or body) node of the transistor 904. Together with the voltage of the source node of the transistor 904 being clamped at or below the pinch off voltage, no unfavorable parasitic junction occurring between the drain node of the transistor 904, semiconductor substrate, and junction isolation tank 910 (e.g., a parasitic NPN structure) generally turns on. The pinch off voltage may be tuned by modifying a position of the junction isolation field plate 130 over the drift well connected to the junction isolation tank 910, modifying a lateral dimension (e.g., a length) of the junction isolation field plate 130, and/or modifying a biasing voltage applied to the junction isolation field plate 130.

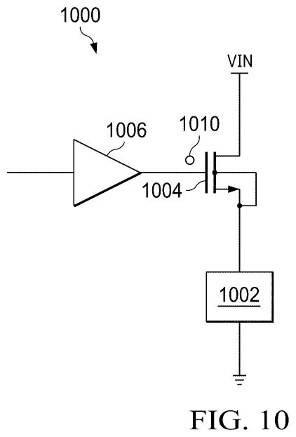

FIG. 10 is a circuit schematic 1000 of an IC in which a semi-floating junction isolation tank is implemented according to some examples. The IC of the circuit schematic 1000 may be on an IC die. The circuit schematic 1000 includes a low side circuit 1002 and a high side transistor 1004. The low side circuit 1002 may be or include any circuit or component thereof (e.g., one or more transistors). For example, the low side circuit 1002 may be part of a power stage (such as in a buck converter), a low voltage switching circuit, or the like. The transistor 1004 may be any transistor in a junction isolation tank 1010, such as the DeMOS illustrated in FIG. 7, an LDMOS, or the like. The junction isolation tank 1010 with junction isolation tank connection mechanism may be like described above with respect to FIG. 1 or FIG. 2.

A voltage input (VIN) node is ohmically, electrically connected to a drain node of the transistor 1004. A substrate (or body) node of the transistor 1004 and a source node of the transistor 1004 are ohmically, electrically connected together and to a node of the low side circuit 1002. A gate node of the transistor 1004 is ohmically, electrically connected to an output node of a driver circuit 1006. The junction isolation tank 1010 is ohmically floating and is semi-floating (e.g., electrically connected to the drain node of the transistor 1004 through a drift well in a first regime) as described above.

The low side circuit 1002 may operate in a voltage range from 0 V to a breakdown voltage of the transistor 1004. Hence, the voltage on the node of the low side circuit 1002 ohmically, electrically connected to the source node may be in a range from 0 V to the breakdown voltage. The breakdown voltage may be increased in some examples, which permits circuits to interface with a higher voltage than otherwise achievable.

In the circuit schematics 800, 900, 1000 of FIGS. 8, 9, and 10, the transistors 804, 904, 914, 1004 are described as having a drain node, a source node, a substrate (or body) node, and a gate node. A drain node may include or correspond to, for example, a drain well and/or drain terminal in the semiconductor substrate 102 (e.g., the epitaxial layer 106) in a corresponding junction isolation tank, like illustrated in FIG. 7. A source node may include or correspond to, for example, a source well and/or source contact region in the semiconductor substrate 102 (e.g., the epitaxial layer 106) in the corresponding junction isolation tank. A substrate (or body) node may include or correspond to, for example, a substrate well and/or substrate contact region in the semiconductor substrate 102 (e.g., the epitaxial layer 106), which is doped with a same conductivity type as the semiconductor substrate 102, in the corresponding junction isolation tank. A gate node may include or correspond to, for example, a gate electrode on or over the semiconductor substrate 102.

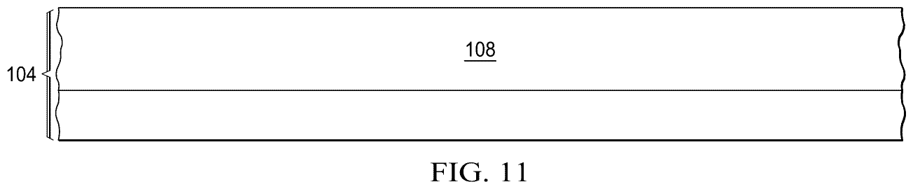

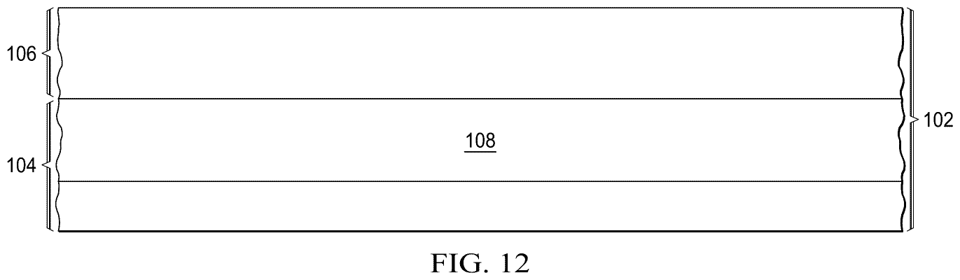

FIGS. 11 through 19 illustrate cross-sectional views of the semiconductor device 400 of FIG. 4 at various stages of manufacturing according to an example method. To avoid unnecessary repetition, doped buried layers, wells, and doped regions are formed by implanting a dopant into the semiconductor substrate 102. To form a doped buried layer, a well, or a doped region by implantation, a photoresist may be deposited (e.g., by spin-on) on or over the semiconductor substrate 102 and patterned using photolithography to expose the area corresponding to where the doped buried layer, well, or doped region is to be formed. Using the patterned photoresist as a mask, an implant is performed to implant the dopant into the semiconductor substrate 102 thereby forming the doped buried layer, well, or doped region. After the implant, the photoresist may be removed, such as by a wet strip or ashing. Examples of dopant types and concentrations of various doped buried layers, wells, and doped regions described in FIGS. 11 through 19 are as described above.

Referring to FIG. 11, a deep buried layer 108 is formed in a semiconductor support substrate 104. The deep buried layer 108 may be formed by implanting dopants into the semiconductor support substrate 104. Referring to FIG. 12, an epitaxial layer 106 is formed on or over the semiconductor support substrate 104. The epitaxial layer 106 may be formed using an epitaxial growth by an appropriate epitaxial growth process, such as low pressure chemical vapor deposition (LPCVD) or the like. The epitaxial layer 106 is doped, such as by in situ during the epitaxial growth. The dopant type and concentration of the epitaxial layer 106 are as described above. In the illustrated example, the semiconductor support substrate 104 and the epitaxial layer 106 form a semiconductor substrate 102. In other examples, another semiconductor substrate may be used. For example, the semiconductor substrate 102 may be a bulk silicon wafer (e.g., without the epitaxial layer 106) with the deep buried layer 108 implanted to a deep depth in the semiconductor substrate 102.

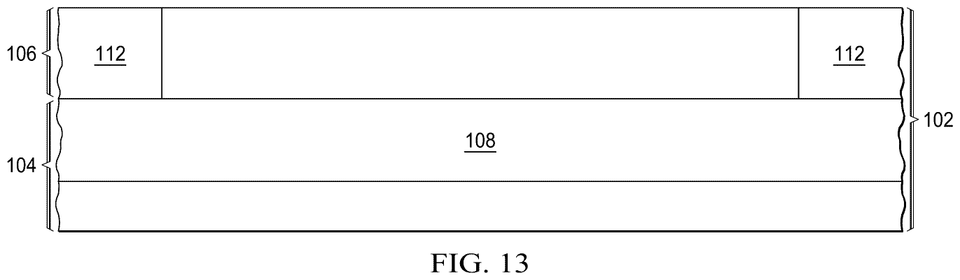

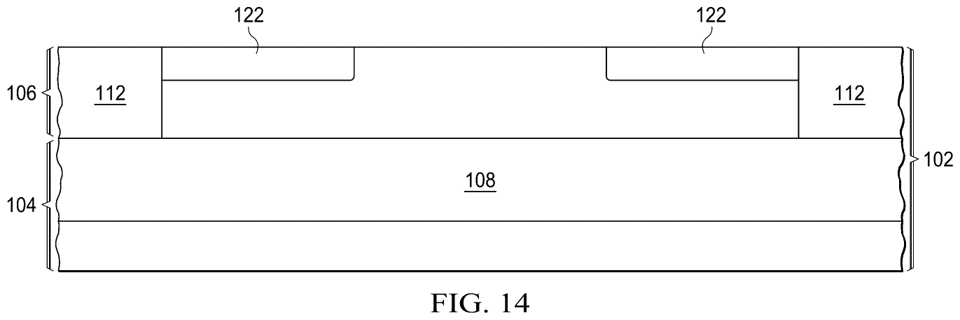

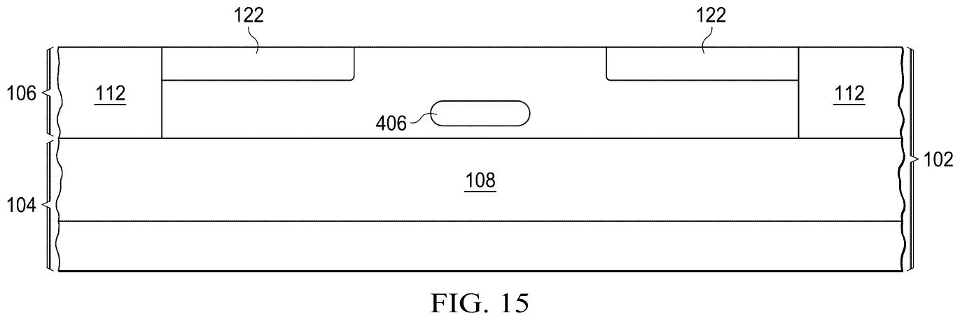

Referring to FIG. 13, a deep well 112 is formed in the semiconductor substrate 102. The deep well 112 may be formed by implanting dopants into the epitaxial layer 106. Referring to FIG. 14, a drift well 122 is formed in the semiconductor substrate 102. The drift well 122 may be formed by implanting dopants into the epitaxial layer 106. Referring to FIG. 15, a buried layer 406 is formed in the semiconductor substrate 102. The buried layer 406 may be formed by implanting dopants into the epitaxial layer 106.

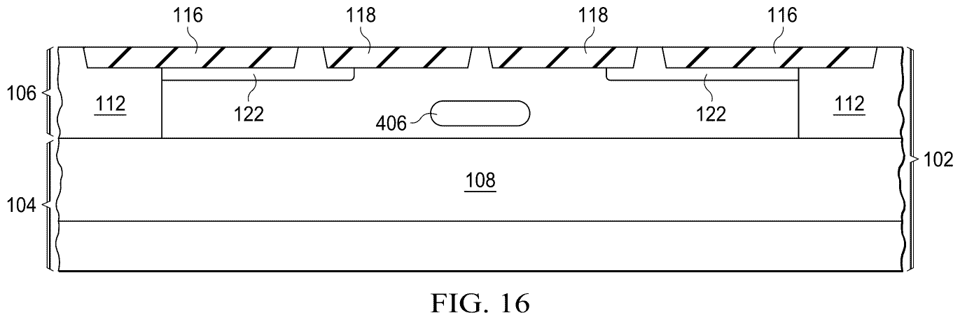

Referring to FIG. 16, dielectric isolation structures 116, 118 are formed in the semiconductor substrate 102. In the illustrated example, the dielectric isolation structures 116, 118 are STIs, and in other examples, the dielectric isolation structures 116, 118 may be or include other dielectric isolation structures, such as field oxide structures, LOCOS structures, stepped gate dielectric structures, or the like. To form the illustrated dielectric isolation structures 116, 118, a hardmask may be deposited on or over the semiconductor substrate 102 and patterned using appropriate photolithography and etching processes. Using the patterned hardmask, trenches are etched into the semiconductor substrate 102. A dielectric material is deposited in the trenches. For example, the dielectric material may be or include a nitride, an oxide, the like, or a combination thereof and may be formed or deposited using in situ steam generation (ISSG) oxidation, atomic layer deposition (ALD), high aspect ratio chemical vapor deposition (HAR-CVD), flowable chemical vapor deposition (FCVD), the like, or a combination thereof. Excess dielectric material and the hardmask may be removed, such as by using a chemical mechanical polish (CMP).

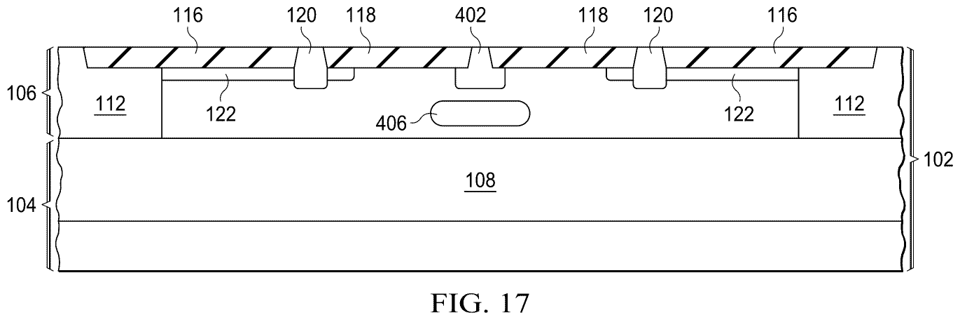

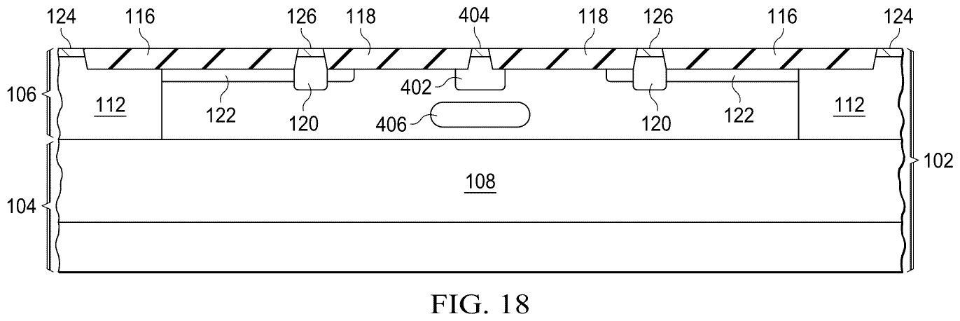

Referring to FIG. 17, a contact well 120 (e.g., a cathode well) and an anode well 402 are formed in the semiconductor substrate 102. The contact well 120 may be formed by implanting dopants into the epitaxial layer 106 in an implantation process, and the anode well 402 may be formed by implanting dopants into the epitaxial layer 106 in another implantation process. Referring to FIG. 18, contact region 124, contact region 126 (e.g., a cathode terminal), and an anode terminal 404 are formed in the semiconductor substrate 102. The contact regions 124, 126 may be formed by implanting dopants into the epitaxial layer 106 in an implantation process, and the anode terminal 404 may be formed by implanting dopants into the epitaxial layer 106 in another implantation process.

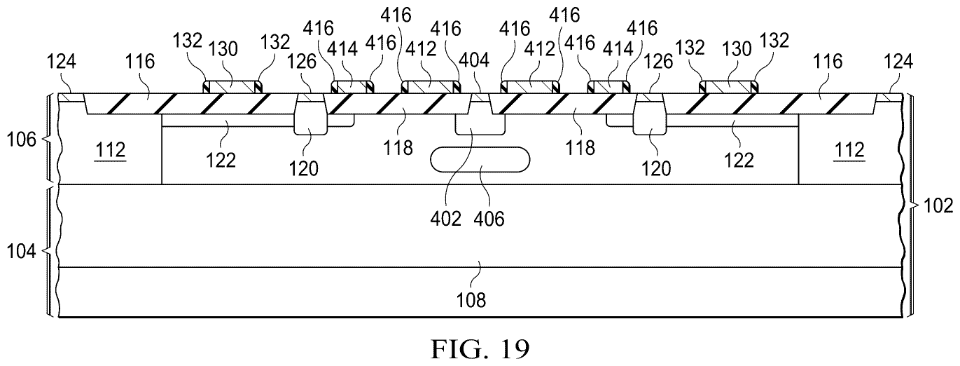

Referring to FIG. 19, a junction isolation field plate 130, an anode field plate 412, and a cathode field plate 414 are formed over the semiconductor substrate 102. A material of the field plates 130, 412, 414 is deposited on or over the semiconductor substrate 102. The material of the field plates 130, 412, 414 may be deposited by any appropriate deposition process, such as chemical vapor deposition (CVD), physical vapor deposition (PVD), or the like. In some examples, such as when the field plates 130, 412, 414 are or include doped polysilicon, the polysilicon may be in situ doped and/or doped by implantation. The material of field plates 130, 412, 414 is then patterned into the field plates 130, 412, 414 using appropriate photolithography and etching processes. In examples in which the device includes one or more gate electrodes, the gate electrode(s) may be formed with the formation of the junction isolation field plate 130.

Dielectric spacers 132, 416 are formed on sidewalls of the field plates 130, 412, 414. A conformal dielectric layer is conformally formed on or over sidewall and upper surfaces of the field plates 130, 412, 414, such as using an appropriate deposition process like CVD or ALD. The conformal dielectric layer is anisotropically etched, such as by reactive ion etch (RIE), which results in the dielectric spacers 132, 416.

Referring to FIG. 4, a dielectric layer 140 is formed over the semiconductor substrate 102. The dielectric layer 140 may include one or multiple dielectric layers formed of any appropriate dielectric material and deposited by any appropriate deposition process, such as CVD, PVD, or the like. Metal contacts 144, 146, 148, 424, 426, 428 are formed through the dielectric layer 140, and metal lines 154, 156, 158, 434, 436, 438 are formed over and on the metal contacts 144, 146, 148, 424, 426, 428, respectively, and over and on the dielectric layer 140. To form the metal contacts, openings are formed through the dielectric layer 140 using photolithography and etching processes. Respective openings expose respective contact regions 124, 126, anode terminal 404, and field plates 130, 412, 414. A barrier and/or adhesion layer may then be conformally deposited, such as by CVD, ALD, or the like, in the openings and over the dielectric layer 140, and a fill metal may be deposited, such as by CVD, PVD, or the like, on the barrier and/or adhesion layer. The barrier and/or adhesion layer and fill metal in the openings form the metal contacts 144, 146, 148, 424, 426, 428. The barrier and/or adhesion layer and fill metal over the dielectric layer 140 may be patterned into the metal lines 154, 156, 158, 434, 436, 438, such as by appropriate photolithography and etching processes.

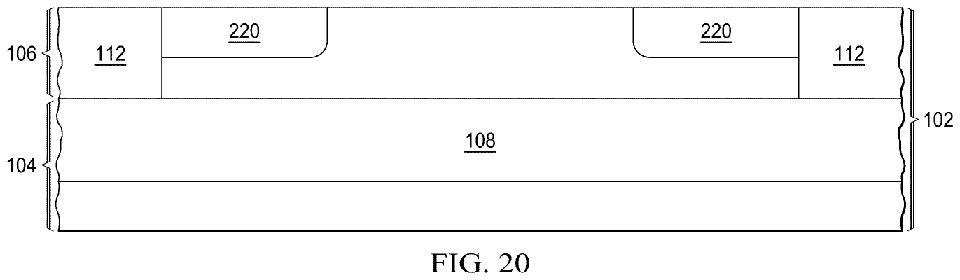

FIGS. 20 through 26 illustrate cross-sectional views of a semiconductor device including a diode (like in FIG. 4) with the junction isolation tank connection mechanism of FIG. 2 at various stages of manufacturing according to an example method. Examples of dopant types and concentrations of various doped buried layers, wells, and doped regions described in FIGS. 20 through 26 are as described above.

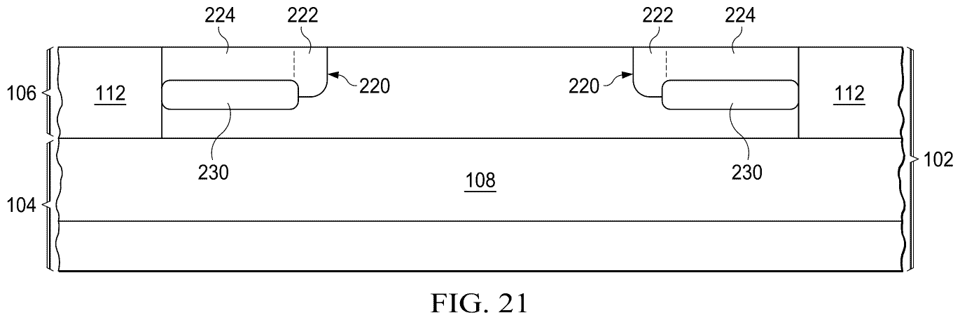

Processing proceeds as described above with respect to FIGS. 11 through 13. Referring to FIG. 20, a well 220 is formed in the semiconductor substrate 102. The well 220 may be formed by implanting dopants into the epitaxial layer 106. Referring to FIG. 21, a buried layer 230 is formed in the semiconductor substrate 102. The buried layer 230 may be formed by implanting dopants into the epitaxial layer 106. As described previously, a portion of the buried layer 230 overlaps with a portion of the well 220. Since a concentration of the dopant of the buried layer 230 is greater than a concentration of the dopant of the well 220, the buried layer 230 dominates in the overlapping portion. This forms a drift well portion 224 of the well 220 over the buried layer 230 and a well portion 222 of the well 220 laterally from the buried layer 230.

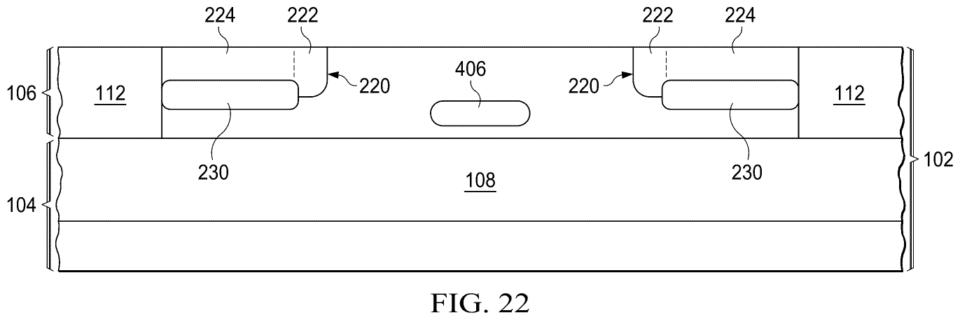

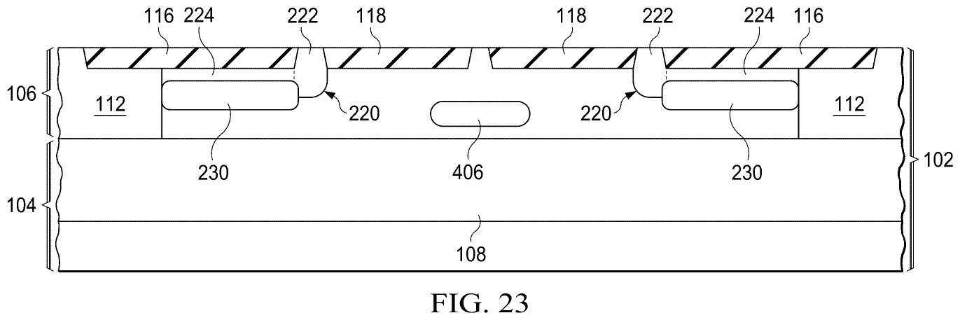

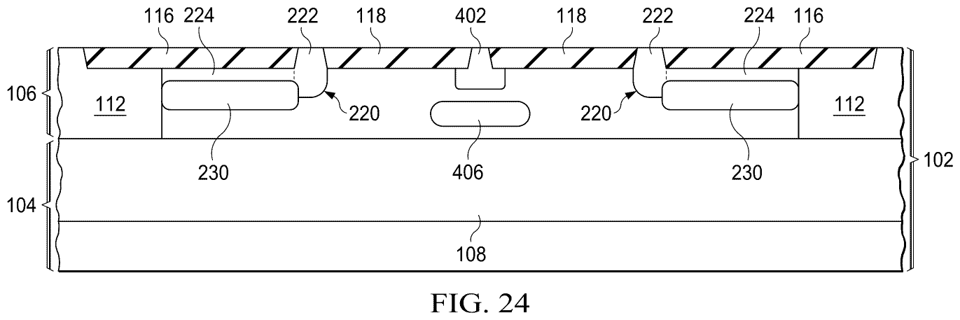

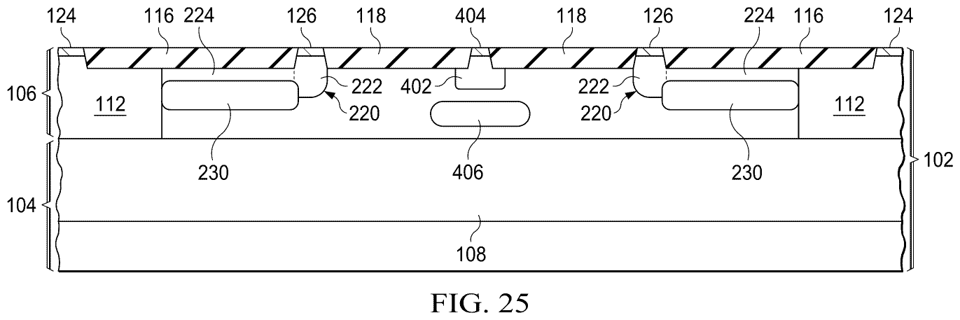

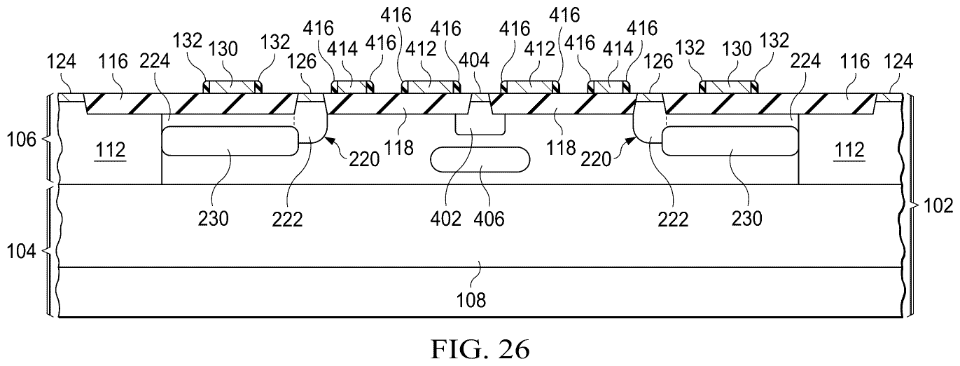

Referring to FIG. 22, a buried layer 406 is formed in the semiconductor substrate 102, like described above with respect to FIG. 15. Referring to FIG. 23, dielectric isolation structures 116, 118 are formed in the semiconductor substrate 102, like described above with respect to FIG. 16. Referring to FIG. 24, an anode well 402 is formed in the semiconductor substrate 102, similar to as described above with respect to FIG. 17. Referring to FIG. 25, contact regions 124, 126 and an anode terminal 404 are formed in the semiconductor substrate 102, like described above with respect to FIG. 18. Referring to FIG. 26, a junction isolation field plate 130, an anode field plate 412, and a cathode field plate 414 are formed over the semiconductor substrate 102, like described above with respect to FIG. 19. Then, a dielectric layer 140 is formed over the semiconductor substrate 102, like described above with respect to FIG. 4. Metal contacts 144, 146, 148, 424, 426, 428 are formed through the dielectric layer 140, and metal lines 154, 156, 158, 434, 436, 438 are formed over and on the metal contacts 144, 146, 148, 424, 426, 428, respectively, and over and on the dielectric layer 140, like described above.

Various other devices may be formed in a junction isolation tank in view of the method described above. Different and/or additional doped buried layers, wells, and/or contact regions may be formed in a semiconductor substrate by implantation like described above.

Different and/or additional field plates and/or gate electrodes may be formed on and over the semiconductor substrate using processing like described above to form the field plates 130, 412, 414. Hence, devices such as the DeMOS of FIG. 7, an LDMOS, or another transistor may be formed.

Although various examples have been described in detail, it should be understood that various changes, substitutions, and alterations can be made therein without departing from the scope defined by the appended claims.

What is claimed is:

1. A semiconductor device comprising:
an epitaxial layer having a first conductivity type, the epitaxial layer being over a semiconductor substrate;
a buried layer having a second conductivity type opposite from the first conductivity type, the buried layer being spaced apart from a top surface of the epitaxial layer;
a deep well having the second conductivity type, the deep well extending in the epitaxial layer and touching the buried layer, the deep well laterally encircling an active area in the epitaxial layer over the buried layer;
a drift well having the second conductivity type, the drift well extending in the epitaxial layer to a first depth, the drift well extending laterally from the deep well toward the active area;
a contact well having the second conductivity type, the contact well extending in the epitaxial layer to a second greater depth and touching the drift well; and
a contact region having the second conductivity type, the contact region extending in the contact well.

2. The semiconductor device of claim 1, wherein the contact well is at least a portion of a device surrounded by the contact region, at least a portion of the device being in the active area.

3. The semiconductor device of claim 2, wherein the buried layer and the deep well are configured to be ohmically electrically floating during operation of the device.

4. The semiconductor device of claim 1, further comprising a diode in the active area, the diode comprising an anode well extending in the epitaxial layer, wherein the contact well is a cathode well of the diode.

5. The semiconductor device of claim 1, further comprising a transistor in the active area, the transistor comprising a source well in the epitaxial layer, wherein the contact well is a drain well of the transistor.

6. The semiconductor device of claim 5, wherein the transistor is a laterally-diffused metal-oxide-semiconductor (LDMOS) transistor.

7. The semiconductor device of claim 5, wherein the transistor is a drain-extended metal-oxide-semiconductor (DeMOS) transistor.

8. The semiconductor device of claim 1, further comprising a field plate over the drift well.

9. The semiconductor device of claim 8, wherein the field plate is ohmically electrically connected to an anode contact terminal of a diode in the active area.

10. The semiconductor device of claim 8, wherein the field plate is ohmically electrically connected to a source contact terminal of a transistor in the active area.

11. The semiconductor device of claim 1, wherein the first conductivity type is p-type, and the second conductivity type is n-type.

12. An integrated circuit comprising:
a first transistor in a first active area in a semiconductor substrate, wherein:
the first transistor includes:
a first source region in the semiconductor substrate;
a first drain region in the semiconductor substrate; and
a first gate electrode over the semiconductor substrate; and
the semiconductor substrate includes:
a first buried layer, the first source region and the first drain region being over the first buried layer;
a first deep well extending to the first buried layer, the first deep well laterally encircling the first active area; and
a first drift well extending laterally from the first deep well and to the first drain region, wherein the first buried layer, the first deep well, the first drift well, and the first drain region are doped by respective dopants having a same conductivity type; and
a field plate over the semiconductor substrate and over the first drift well, the field plate being laterally between the first deep well and the first drain region.

13. The integrated circuit of claim 12, wherein the field plate is ohmically electrically connected to the first source region.

14. The integrated circuit of claim 12, wherein the first buried layer and the first deep well are configured to be ohmically electrically floating during operation of the first transistor.

15. The integrated circuit of claim 12, further comprising a second transistor in a second active area in the semiconductor substrate, wherein:
the second transistor includes:
a second source region in the semiconductor substrate;
a second drain region in the semiconductor substrate, the second drain region being ohmically electrically connected to the first source region; and
a second gate electrode over the semiconductor substrate; and
the semiconductor substrate further includes:
a second buried layer, the second source region and the second drain region being over the second buried layer; and
a second deep well extending to the second buried layer, the second deep well laterally encircling the second active area, wherein the second buried layer, the second deep well, and the second drain region are doped by respective dopants having the same conductivity type as the first buried layer.

16. The integrated circuit of claim 15, wherein the second source region is ohmically electrically connected to the second buried layer and the second deep well.

17. A method of forming a semiconductor device, the method comprising:
forming a buried layer in a semiconductor substrate, the buried layer having a first conductivity type;
forming an epitaxial layer over the semiconductor substrate, the epitaxial layer having a second conductivity type opposite from the first conductivity type, the buried layer being spaced apart from a top surface of the epitaxial layer;
forming a deep well extending in the epitaxial layer and touching the buried layer, the deep well laterally encircling an active area in the epitaxial layer over the buried layer, the deep well having the first conductivity type;
forming a drift well extending in the epitaxial layer, the drift well extending laterally from the deep well towards the active area, the drift well having the first conductivity type; and
forming a contact well extending in the epitaxial layer and touching the drift well, the contact well having the first conductivity type; and
forming a contact region extending in the epitaxial layer and in the contact well, the contact region having the first conductivity type.

18. The method of claim 17, further comprising forming a device surrounded by the contact region in the active area, wherein the contact well is a portion of the device.

19. The method of claim 18, wherein the buried layer and the deep well are configured to be ohmically electrically floating during operation of the device.

20. The method of claim 17, further comprising forming a field plate over the drift well.

21. The method of claim 20, wherein the field plate is ohmically electrically connected to an anode terminal of a diode in the active area.

22. The method of claim 20, wherein the field plate is ohmically electrically connected to a source contact of a transistor in the active area.
